(19) United States
(12) Patent Application Publication
(10) Pub. No.: US 2015/0340459 A1
(43) Pub. Date: Nov. 26, 2015

(54) METHOD OF FORMING PATTERNS OF SEMICONDUCTOR DEVICE

(71) Applicant: Samsung Electronics Co., Ltd., Suwon-si (KR)

(72) Inventor: CHUL LEE, Seoul (KR)

(21) Appl. No.: 14/668,989

(22) Filed: Mar. 26, 2015

(30) Foreign Application Priority Data
May 21, 2014 (KR) 10-2014-0061015

(51) Int. Cl. H01L 29/66; H01L 21/31; H01L 21/283; H01L 21/32; H01L 21/311

(52) U.S. Cl. CPC H01L 29/66477; H01L 21/32; H01L 21/31144; H01L 21/283; H01L 21/31

(57) ABSTRACT

A method of manufacturing a semiconductor device includes forming a substrate; forming a plurality of first patterns on the substrate, the plurality of first patterns spaced apart from each other in the first direction and extending in a second direction, each first pattern having two opposite end portions in the second direction, and each first pattern having at least one different end portion location in the second direction from a corresponding end portion location of at least one adjacent first pattern; and using the plurality first patterns to form a plurality of respective conductive lines in a plurality of gaps formed in the substrate, the gaps corresponding to and formed to have the same shapes as the plurality of first patterns when viewed from a plan view.

### CROSS-REFERENCE TO RELATED APPLICATIONS

This U.S. non-provisional patent application claims priority under 35 U.S.C. §119 to Korean Patent Application No. 10-2014-0061015, filed on May 21, 2014, in the Korean Intellectual Property Office, the entire contents of which are hereby incorporated by reference.

### BACKGROUND OF THE INVENTION

As a design rule of a semiconductor device decreases, it becomes useful to form fine patterns, allowing for the realization of highly-integrated semiconductor devices. For example, a double patterning technology (DPT) may be used to form a fine pattern, whose dimension is smaller than the minimum size that can be achieved by a photolithography process.

The double-patterning technology may be generally classified into a self-alignment double patterning (SADP) process and a self-alignment reversed patterning (SARP) process. The SARP process may include steps of forming spacers on both sidewalls of each pattern of a set of patterns, selectively removing the patterns, and patterning an underlying layer using the spacers as an etch mask. The SADP process may include steps of forming spacers on first patterns, forming second patterns between the spacers, removing the spacers, and patterning an underlying layer using the first and second patterns as an etch mask.

### SUMMARY

Example embodiments of the inventive concept relate to a method of fabricating a semiconductor device, and in particular, to a method of forming fine gaps of a semiconductor device.

Example embodiments of the inventive concept provide a method of forming patterns of a semiconductor device using a self-alignment double patterning (SADP) process.

According to example embodiments of the inventive concept, a method of manufacturing a semiconductor device includes: forming a plurality of first mask patterns on a substrate, the plurality of first mask patterns being arranged along a first direction and extending in a second direction; forming a plurality of second mask patterns on the substrate arranged along the first direction, each second mask pattern disposed between two first mask patterns and extending in the second direction; forming a sacrificial layer to enclose the first mask patterns, the sacrificial layer comprising first portions disposed on sidewalls of the first mask patterns to face each other in the first direction and second portions disposed at ends of the first mask patterns to connect the first portions to each other; and removing the second portions of the sacrificial layer using a trimming mask pattern as an etch mask to form sacrificial patterns spaced apart from each other in the first direction, each sacrificial pattern having two opposite end portions in the second direction. Each sacrificial pattern may have at least one different end portion location in the second direction from a corresponding end portion location of at least one adjacent sacrificial pattern.

According to another embodiment, a method of manufacturing a semiconductor device includes: forming a substrate; forming a plurality of first patterns on the substrate, the plurality of first patterns spaced apart from each other in a first direction and extending in a second direction, each first pattern having two opposite end portions in the second direction, and each first pattern having at least one different end portion location in the second direction from a corresponding end portion location of at least one adjacent first pattern; and using the plurality first patterns to form a plurality of respective conductive lines in a plurality of gaps formed in the substrate, the gaps corresponding to and formed to have the same shapes as the plurality of first patterns when viewed from a plan view.

According to yet another embodiment, a method of manufacturing a semiconductor device includes: forming a substrate; and forming a plurality of sacrificial patterns on the substrate, the plurality of sacrificial patterns spaced apart from each other in a first direction and extending in a second direction, each sacrificial pattern having two opposite end portions in the second direction, wherein each sacrificial pattern has two end portions having end portion locations in the second direction different from corresponding end portion locations of two end portions of at least one adjacent sacrificial pattern, and wherein the sacrificial patterns are formed using a trimming mask that includes a first side that has a zig-zag shape when viewed in a plan view.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIGS. 1A through 13A and FIGS. 7C and 8C are plan views illustrating a method of forming patterns for a semiconductor device, according to example embodiments of the inventive concept.

FIGS. 1B through 13B are sectional views, which are taken along line I-I′ of FIGS. 1A through 13A and FIGS. 7C and 8C to illustrate a method of forming patterns for a semiconductor device according to example embodiments of the inventive concept.

FIGS. 14A through 18A and FIGS. 14C and 15C are plan views illustrating a method of forming patterns for a semiconductor device, according to other example embodiments of the inventive concept.

FIGS. 14B through 18B are sectional views, which are taken along line II-IP of FIGS. 14A through 18A and FIGS. 14C and 15C to illustrate a method of forming patterns for a semiconductor device according to other example embodiments of the inventive concept.

FIGS. 19 and FIGS. 20 are plan views illustrating a problem of the prior art.

FIG. 21 is a schematic block diagram illustrating an example of electronic systems including a semiconductor device fabricated by a patterning method according to embodiments of the inventive concept.

FIG. 22 is a schematic block diagram illustrating another example of electronic systems including a semiconductor memory device fabricated by a patterning method according to embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein. In the drawings, the thicknesses of layers and regions are exaggerated for clarity. Like reference numerals in the drawings denote like elements, and thus their descriptions may be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, or as “contacting” another element, there are no intervening elements present. Other words used to describe the relationship between elements or layers should be interpreted in a like fashion (e.g., “between” versus “directly between,” “adjacent” versus “directly adjacent,” “on” versus “directly on”).

As used herein the term “and/or” includes any and all combinations of one or more of the associated listed items. In addition, it will be understood that, although the terms “first”, “second”, etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below could be termed a second element, component, region, layer or section without departing from the teachings of example embodiments. For example, in some cases, the claims my use the terms “first,” “second,” etc. when referring to a component that may not be named or referred to as such in the specification.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to limit the scope of example embodiments.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

Terms such as “same,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

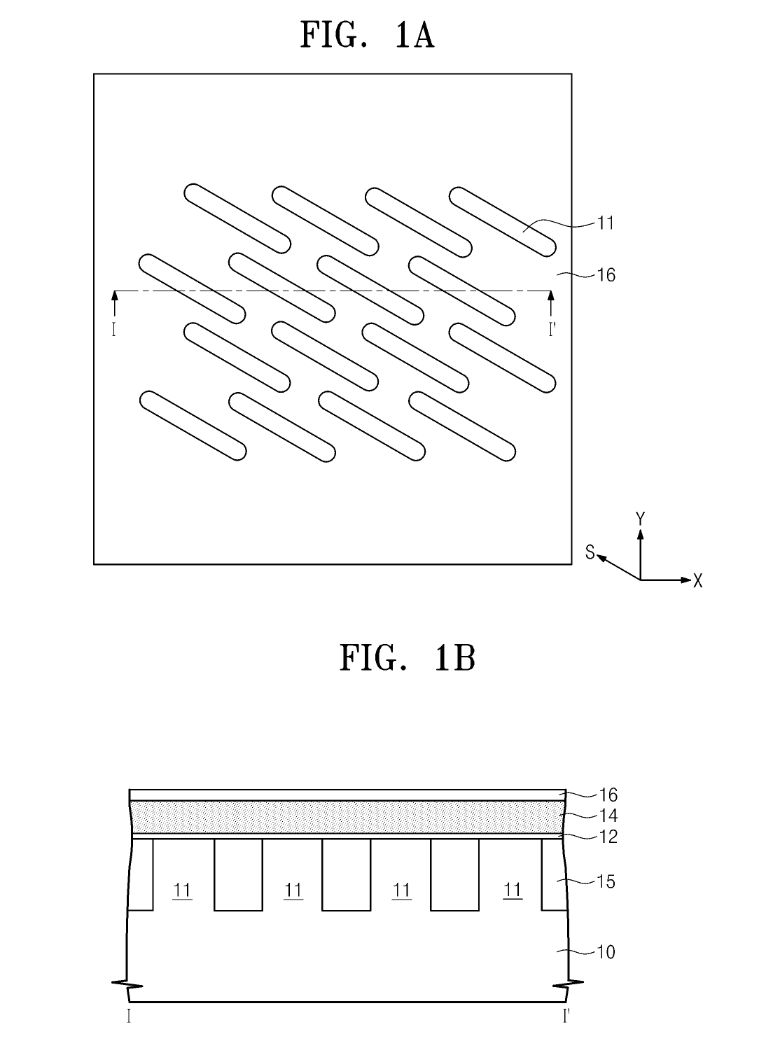

FIGS. 1A through 13A and FIGS. 7C and 8C are plan views illustrating a method of forming patterns for a semiconductor device, according to example embodiments of the inventive concept. FIGS. 1B through 13B are sectional views, which are taken along line I-I′ of FIGS. 1A through 13A and FIGS. 7C and 8C to illustrate a method of forming patterns for a semiconductor device according to example embodiments of the inventive concept.

Referring to FIGS. 1A and 1B, a first thin-film 12, a carbon-containing layer 14, and a second thin-film 16 may be sequentially formed on a substrate 10.

The substrate 10 may be, for example, a silicon wafer. The substrate 10 may include a plurality of active regions 11. Each active region 11 may be defined by device isolation layers 15 formed on the substrate 10. For example, a device isolation layer 15 may be formed in trenches in the substrate 11, and the active regions 11 may be formed to be surrounded by these trenches. The trenches may include insulative material that forms the device isolation layers 15. In one embodiment, each active region 11 may have an elongated island shape and may be arranged along a first direction (e.g., an s direction as shown in FIG. 1A).

In one embodiment, the first thin-film 12 is formed of or includes an oxide. For example, the first thin-film 12 may be formed of at least one of thermal oxide, CVD oxide, un-doped silicate glass (USG), or high density plasma (HDP) oxide.

The carbon-containing layer 14 may be formed of a carbon-based material. In example embodiments, the carbon-containing layer 14 may be formed of a carbon- and hydrogen-containing layer or carbon-, hydrogen-, and oxygen-containing layer. Further, the carbon-containing layer 14 may have a relatively high carbon content, for example, of about 80-99 wt % relative to a total weight of a compound constituting the carbon-containing layer 14. The carbon-containing layer 14 may be, for example, an amorphous carbon layer.

The second thin-film 16 may include a material having an etch selectivity with respect to the carbon-containing layer 14. For example, in certain embodiments, the second thin-film 16 may be formed of or include a silicon oxide layer, a silicon nitride layer, or a poly-silicon layer.

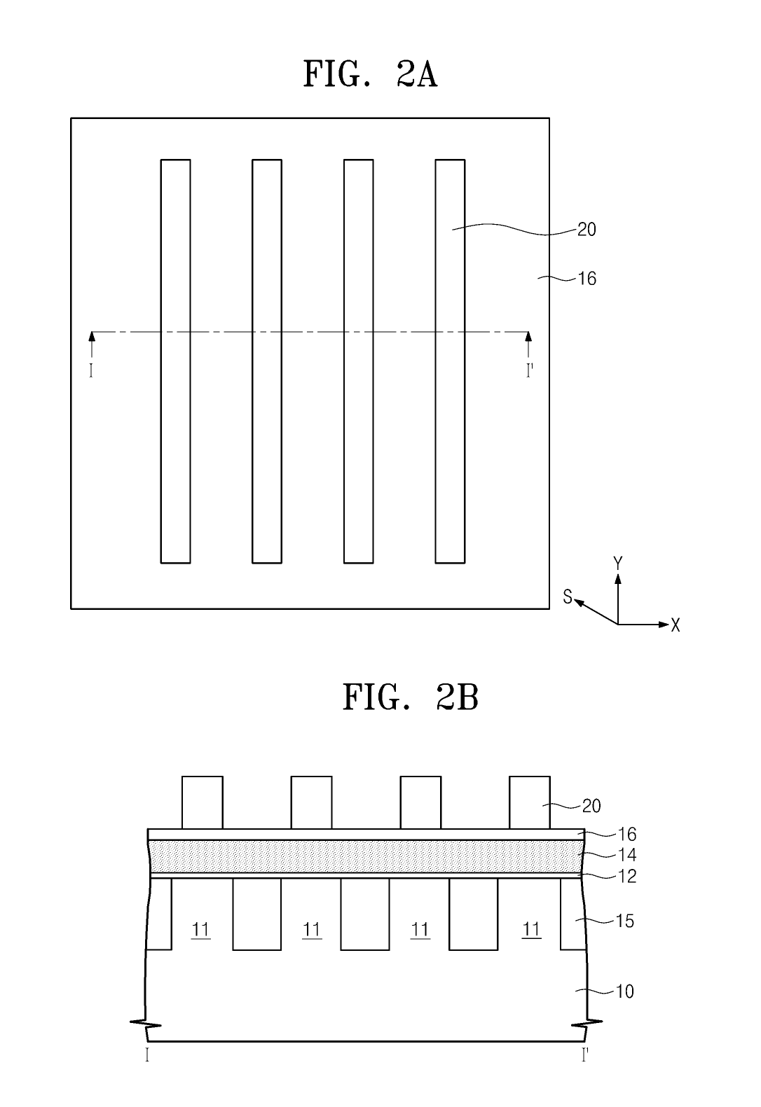

In order to reduce complexity in the drawings and to provide better understanding of example embodiments of the inventive concepts, the active region 11 is omitted from FIGS. 2A through 12A and FIGS. 7C and 8C.

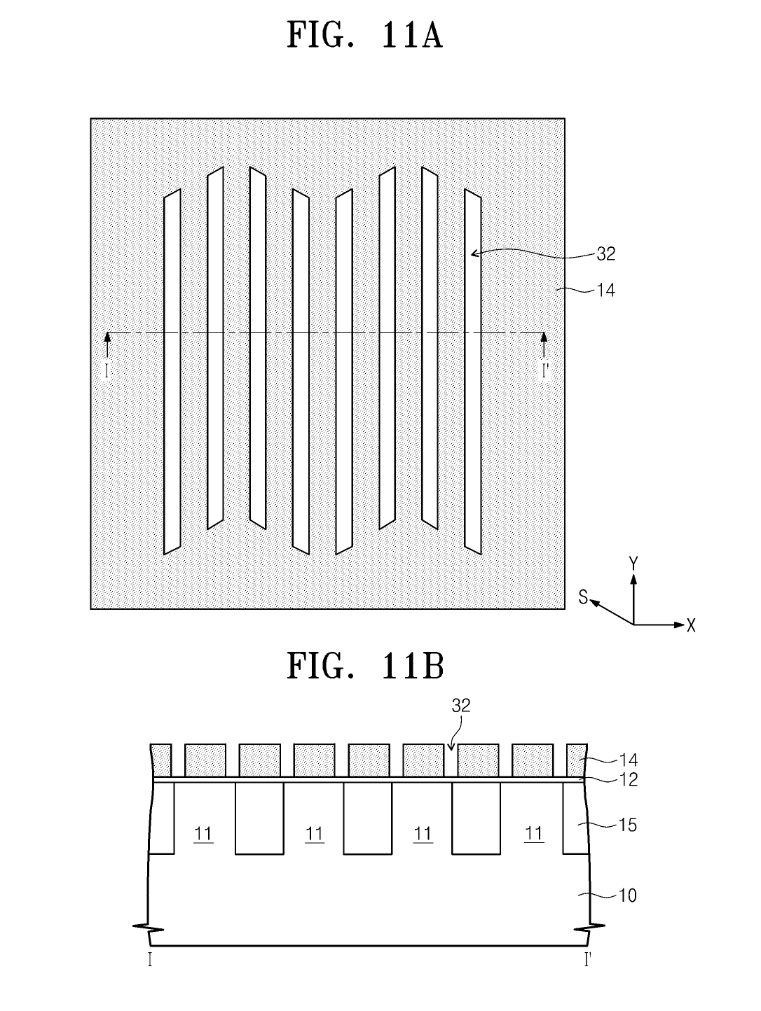

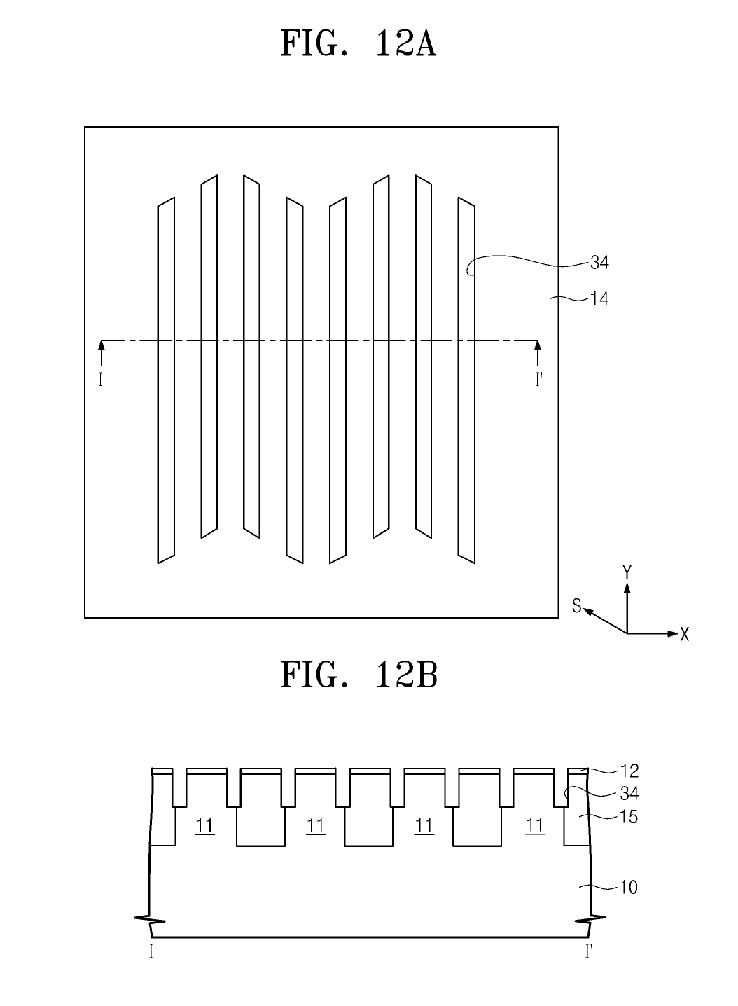

Referring to FIGS. 2A and 2B, a plurality of first mask patterns 20 may be formed. The various patterns described herein may be described in connection with an overall pattern including multiple sub-patterns, or maybe described to refer to one of the sub-patterns. For example, with respect to FIGS. 2A and 2B, each raised bar structure 20 may be referred to as a first mask pattern, or the entire structure including a plurality of raised bar structures 20 may be referred to as a pattern. The first mask patterns 20 may be arranged on the substrate 10 to be spaced apart from each other in a second or x direction and may extend in a third or y direction that is orthogonal to the second or x direction. Widths of the first mask patterns 20 may determine distances between fine gaps (e.g., see 34 of FIGS. 12A and 12B), which will be formed in a subsequent process. In certain embodiments, the first mask patterns 20 may include a material having an etch selectivity with respect to the second thin-film 16. The first mask patterns 20 may be formed, for example, by a spin-on-hardmask (SOH) layer. In certain embodiments, the SOH layer may be a carbon-based SOH layer or a silicon-based SOH layer.

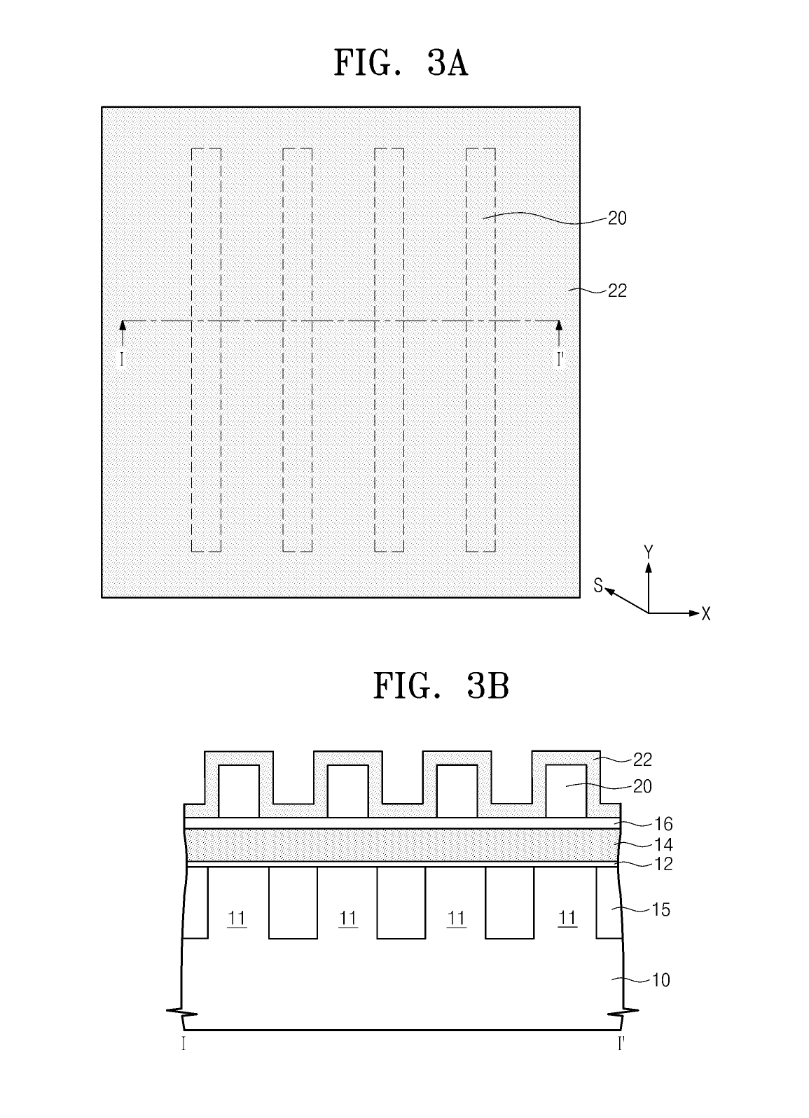

Referring to FIGS. 3A and 3B, a sacrificial layer 22 may be formed to cover side and top surfaces of the first mask patterns 20 and a top surface of the second thin-film 16 exposed by the first mask patterns 20. For example, the sacrificial layer 22 may be conformally formed on side and top surfaces of the first mask patterns 20 and a top surface of the second thin-film 16 exposed by the first mask patterns 20. The sacrificial layer 22 at this stage may be referred to as a preliminary sacrificial layer. In one embodiment, the sacrificial layer 22 may be formed to partially fill gap regions between the first mask patterns 20. For example, a horizontal thickness of the sacrificial layer 22 on the side surfaces of the first mask patterns 20 may be smaller than half the width between the first mask patterns 20. In certain embodiments, the horizontal thickness of the sacrificial layer 22 on the side surfaces of the first mask patterns 20 is equal to or smaller one fourth a width between the first mask patterns 20. A horizontal thickness of the sacrificial layer 22 may determine a width of each of the fine gaps (e.g., 34 of FIGS. 12A and 12B), which will be formed in the substrate 10 in the subsequent process. The sacrificial layer 22 may be formed, for example, by an atomic layer deposition (ALD) process. In one embodiment, the sacrificial layer 22 is formed of or includes a silicon oxide layer.

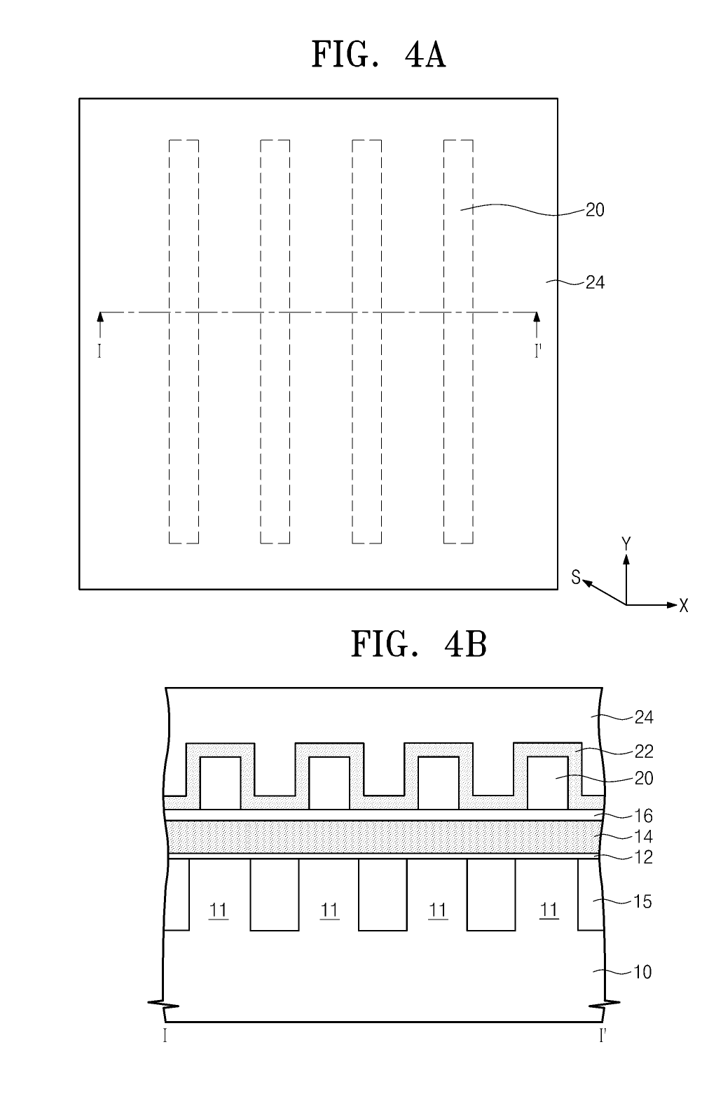

Referring to FIGS. 4A and 4B, a second mask layer 24 may be formed on the sacrificial layer 22. The second mask layer 24 may be formed to completely fill gaps between the first mask patterns 20. In one embodiment, the second mask layer 24 may be formed of a spin on hardmask (SOH) layer. The SOH layer may be, for example, a carbon-based SOH layer or a silicon-based SOH layer.

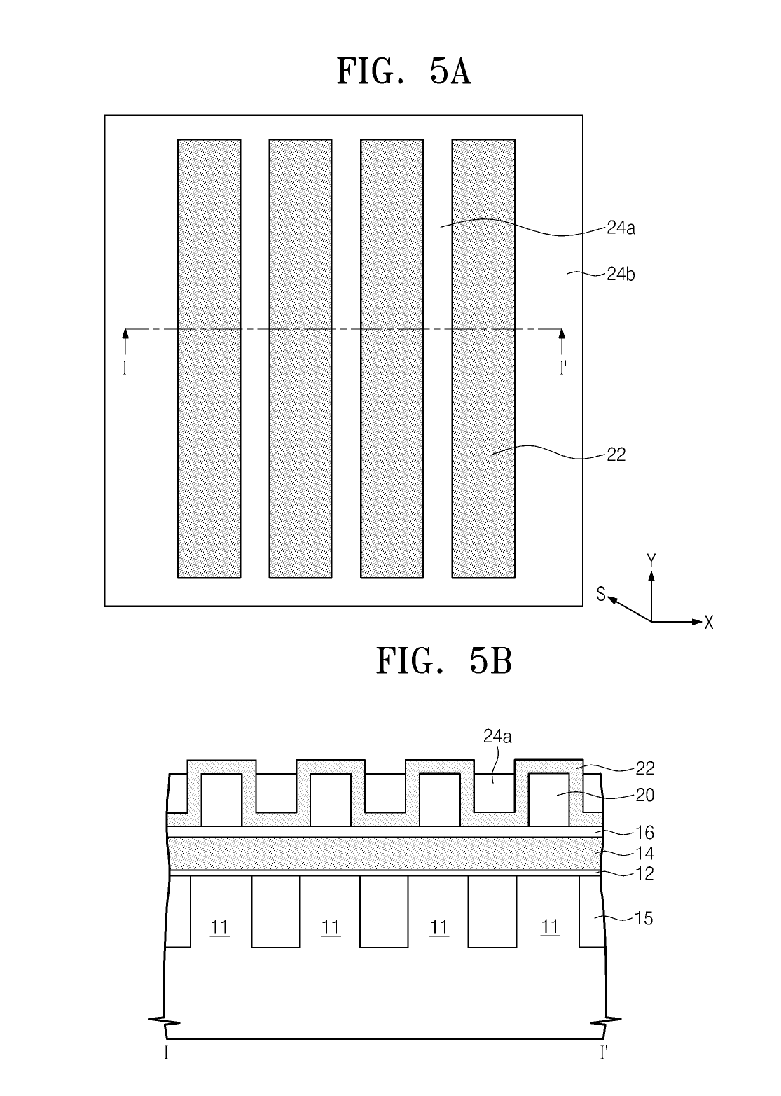

Referring to FIGS. 5A and 5B, the second mask layer 24 may be partially removed to expose a top surface of the sacrificial layer 22 and form second mask patterns 24a and a third mask pattern 24b. The second mask patterns 24a may be formed between the first mask patterns 20. The third mask pattern 24b may be formed outside the second mask patterns 24a to connect the second mask patterns 24a to each other. The second mask patterns 24a may be arranged on the substrate 10 to be spaced apart from each other in the second or x direction and extend in the third or y direction. For example, when viewed in plan view, the first and second mask patterns 20 and 24a may be alternatingly disposed in the second or x direction, and the sacrificial layer 22 may be disposed between the first and second mask patterns 20 and 24a. The top surface of the sacrificial layer 22 may be exposed between adjacent ones of the second mask patterns 24a. In example embodiments, the second mask patterns 24a may be formed to have top surfaces that are coplanar with those of the first mask patterns 20. Widths of the second mask patterns 24a may determine distances between the fine gaps (e.g., see 34 of FIGS. 12A and 12B), which will be formed in the subsequent process.

The partial removal of the second mask layer 24 may include partially etching an upper portion thereof using, for example, a dry etching process or an etch-back process.

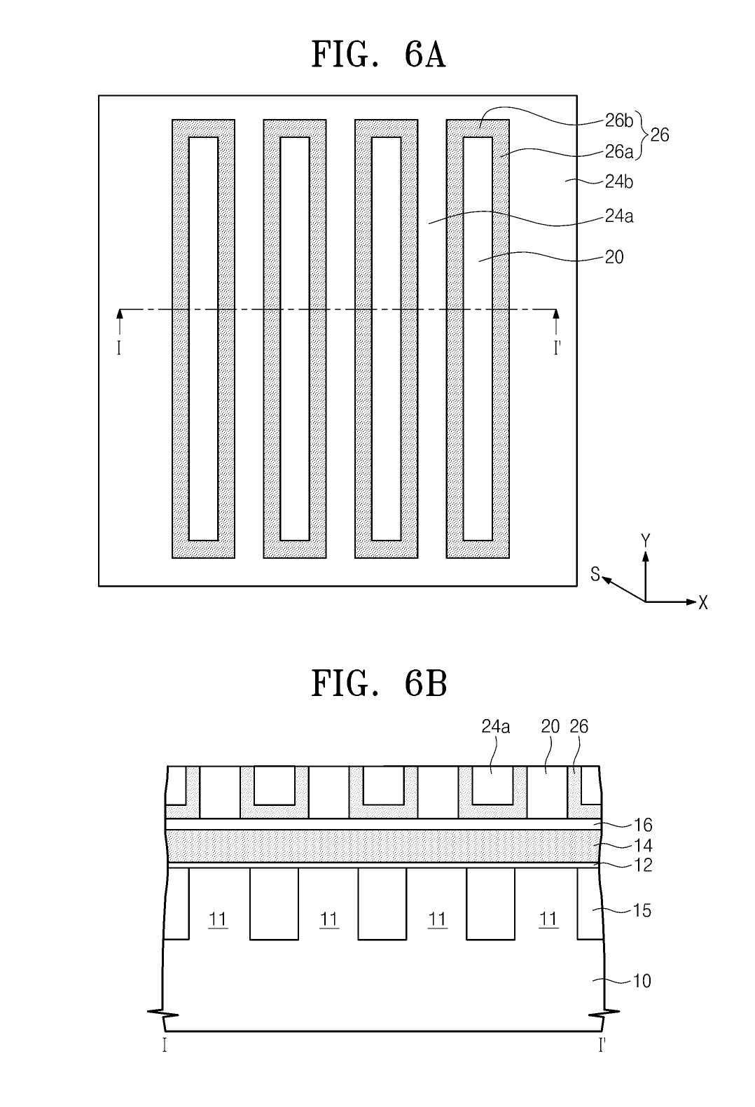

Referring to FIGS. 6A and 6B, the sacrificial layer 22 may be partially etched to open the top surfaces of the first mask patterns 20. Sacrificial patterns 26 may be formed between the first mask patterns 20 and the second mask patterns 24a. For example, each of the sacrificial patterns 26 may include a pair of first sacrificial patterns 26a spaced apart from each other in the second or x direction and a pair of second sacrificial patterns 26b being parallel to the second or x direction and connecting the pair of first sacrificial patterns 26a. The sacrificial patterns 26 may be formed on the sidewalls of the first mask patterns 20.

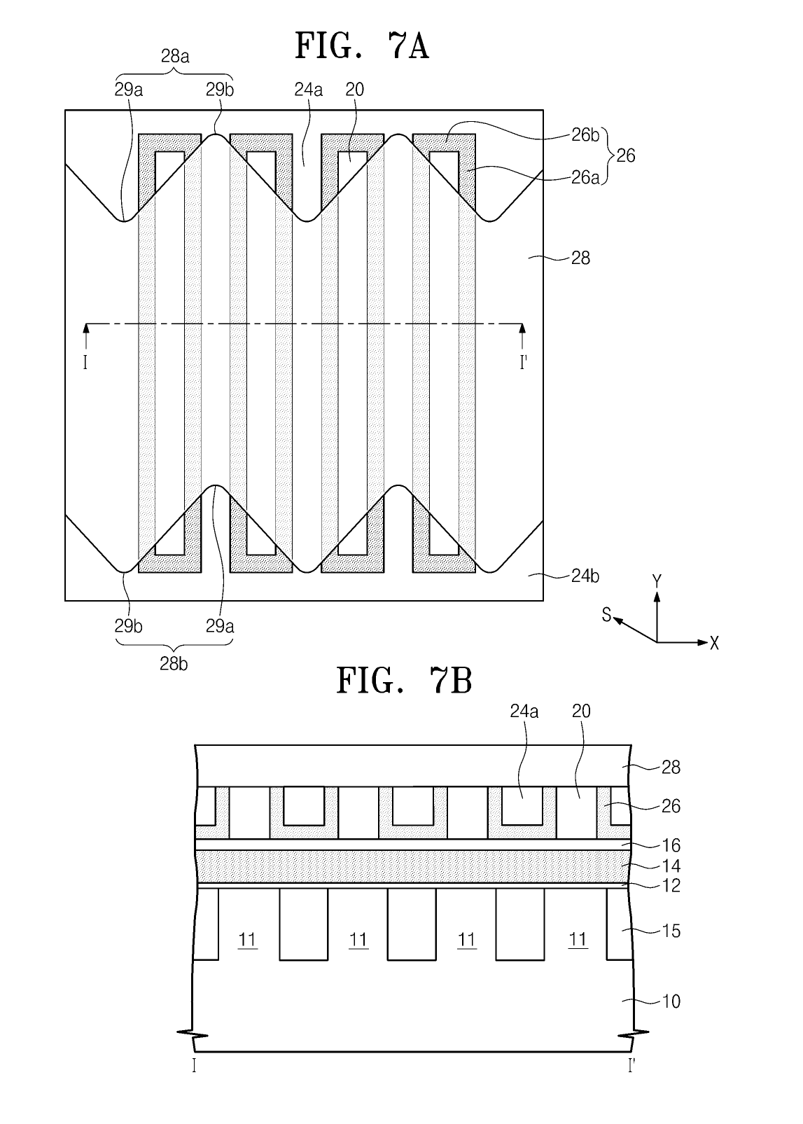

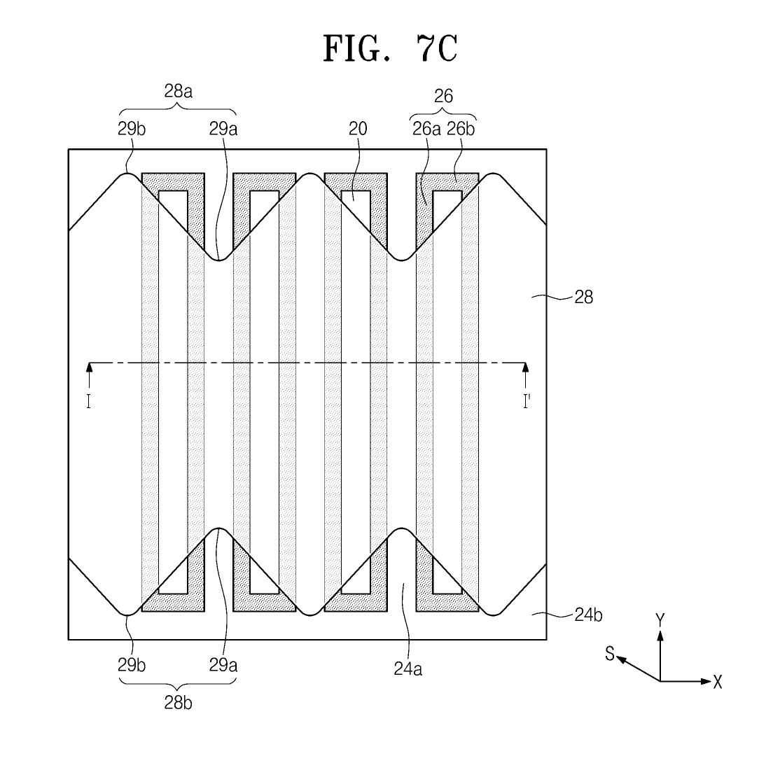

Referring to FIGS. 7A through 7C, a trimming mask pattern 28 may be formed on the first to third mask patterns 20, 24a, and 24b provided with the sacrificial pattern 26. The trimming mask pattern 28 may be formed to cross the first to third mask patterns 20, 24a, and 24b and expose portions of the sacrificial patterns 26.

The trimming mask pattern 28 may have a first side 28a and a second side 28b facing (e.g., opposite) each other. The first and second sides 28a and 28b of the trimming mask pattern 28 may be formed to cross the first to third mask patterns 20, 24a, and 24b, and thus, the trimming mask pattern 28 may expose the second sacrificial pattern 26b. Each of the first and second sides 28a and 28b may include a plurality of first curved portions 29a and a plurality of second curved portions 29b. When viewed in plan view, the first and second curved portions 29a and 29b of each side may be curved toward two opposite directions. For example, the first curved portion 29a may be concavely curved, whereas the second curved portion 29b may be convexly curved. The first and second curved portions 29a and 29b may be alternatingly disposed in each of the first and second sides 28a and 28b, and thus, each of the first and second sides 28a and 28b may be shaped like a sinusoidal or triangular waveform, for example in a zig-zag manner. Also, the curved portions 29a and 29b described herein may be more generally referred to as bent portions. These bent portions are shown as being curved in the figures, but need not have a rounded curve. For example, the bent portions may have a substantially angled orientation where two straight portions meet.

In example embodiments, as shown in FIG. 7A, when viewed in plan view, the first side 28a may be formed in such a way that the first curved portions 29a thereof face (e.g., are opposite) the second curved portions 29b of the second side 28b.

In other example embodiments, as shown in FIG. 7C, when viewed in plan view, the first side 28a may be formed in such a way that the first curved portions 29a thereof face (e.g., are opposite) the first curved portions 29a of the second side 28b. With respect to FIGS. 7A and 7C, each example shows a trimming mask pattern that has protrusions (in a y direction) at second curved portions 29b and that has recesses (in a y direction) at first curved portions 29a.

The first and second curved portions 29a and 29b may be provided on the second mask patterns 24a and may be connected to each other by sides that are at an angle to the second or x direction. The sides may be linear, for example. In the embodiment of FIG. 7A, the first and second sides 28a and 28b may be described as having zig-zag shapes that have the same phase, while in the embodiment of FIG. 7C, the first and second sides 28a and 28b may be described as having zig-zag shapes that have an opposite phase or are 180 degrees out of phase with each other. In certain embodiments, each of the first and second sides may have a triangular, square, sawtooth, sinusoidal, or other periodic waveform shape.

The trimming mask pattern 28 may be, for example, a photoresist pattern.

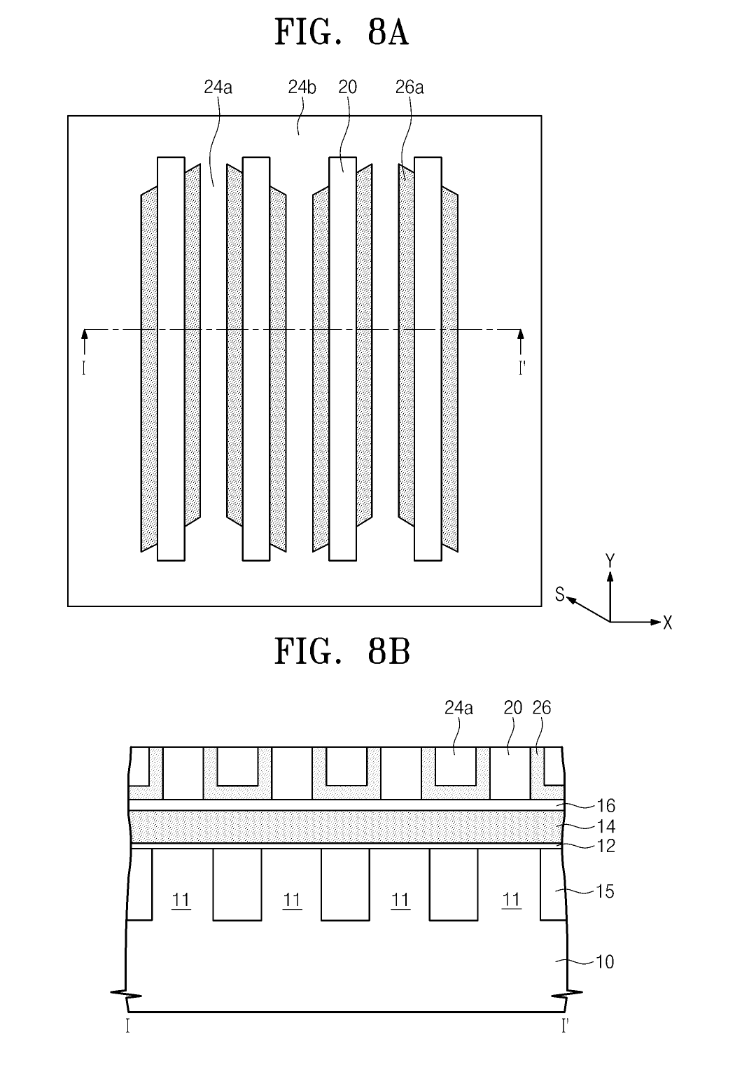

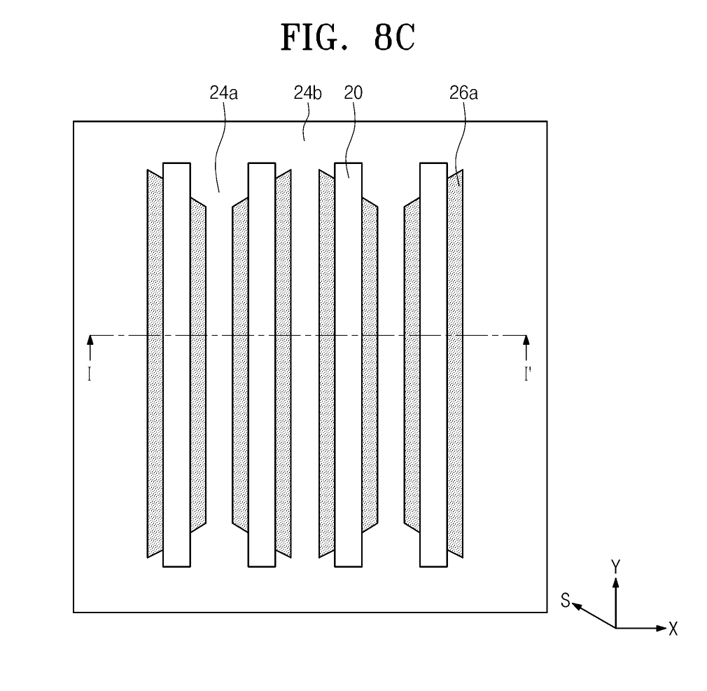

Referring to FIGS. 8A through 8C, the second sacrificial pattern 26b may be removed using the trimming mask pattern 28 as an etch mask. The removal of the second sacrificial pattern 26b may be performed using, for example, a dry etching process. Since the trimming mask pattern 28 is used as the etch mask, the first sacrificial patterns 26a may remain between the first and second mask patterns 20 and 24a. The first sacrificial patterns 26a may be formed spaced apart from each other in the second or x direction. In one embodiment, portions of the first sacrificial patterns 26a are removed along with the removal of the second sacrificial patterns 26b.

In example embodiments, as shown in FIG. 8A, each of the first sacrificial patterns 26a may have substantially the same length. A pair of the first sacrificial patterns 26a disposed at both (e.g., opposite) sides of each first mask pattern 20 may have end portions that are at an angle to the second or x direction and are located at different positions in the y direction. A pair of the first sacrificial patterns 26a disposed at opposite sides of each second mask pattern 24a may have end portions located at the same position in the y direction. The first sacrificial patterns 26a disposed at opposite sides of the second mask patterns 24a may have different shapes. For example, they may be disposed to have mirror symmetry with respect to the second mask patterns 24a. The corresponding end portions of these adjacent sacrificial patterns 26a may be angled in a different direction. Further, as shown in FIG. 8A, and also 8C, certain corresponding end portions of two adjacent first sacrificial patterns 26a may be arranged linearly with respect to each other along a line that is angled with respect to the first direction.

In other example embodiments, as shown in FIG. 8C, a pair of the first sacrificial patterns 26a disposed at opposite sides of the first mask patterns 20 may have different lengths. The pair of adjacent first sacrificial patterns 26a disposed at opposite sides of the first mask patterns 20 may have end portions that are at an angle to the second or x direction and are located at different positions in the y direction. A pair of adjacent first sacrificial patterns 26a disposed at opposite sides of the second mask patterns 24a may have substantially the same length. The pair of the first sacrificial patterns 26a disposed at opposite sides of the second mask patterns 24a may have end portions located at the same position in the y direction. In the example shown in FIG. 8C, opposite end portions of each first sacrificial pattern 26a are angled at a different angle with respect to the x direction.

The trimming mask pattern 28 may be removed after the removal of the second sacrificial pattern 26b.

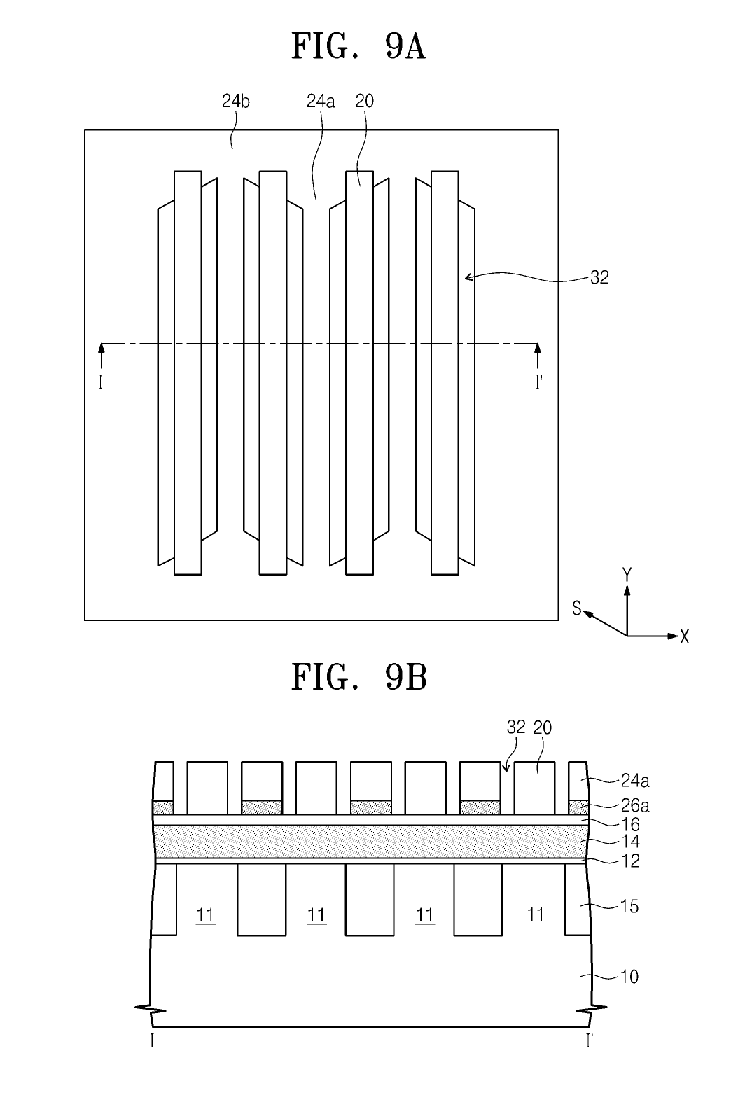

Referring to FIGS. 9A and 9B, the first sacrificial patterns 26a may be selectively etched using the first to third mask patterns 20, 24a, and 24b as an etch mask to expose the top surface of the second thin-film 16. Accordingly, openings 32 may be formed between the first and second mask patterns 20 and 24a. Since the second mask patterns 24a are used as the etch mask, portions of the first sacrificial patterns 26a may remain between the second thin-film 16 and the second mask patterns 24a.

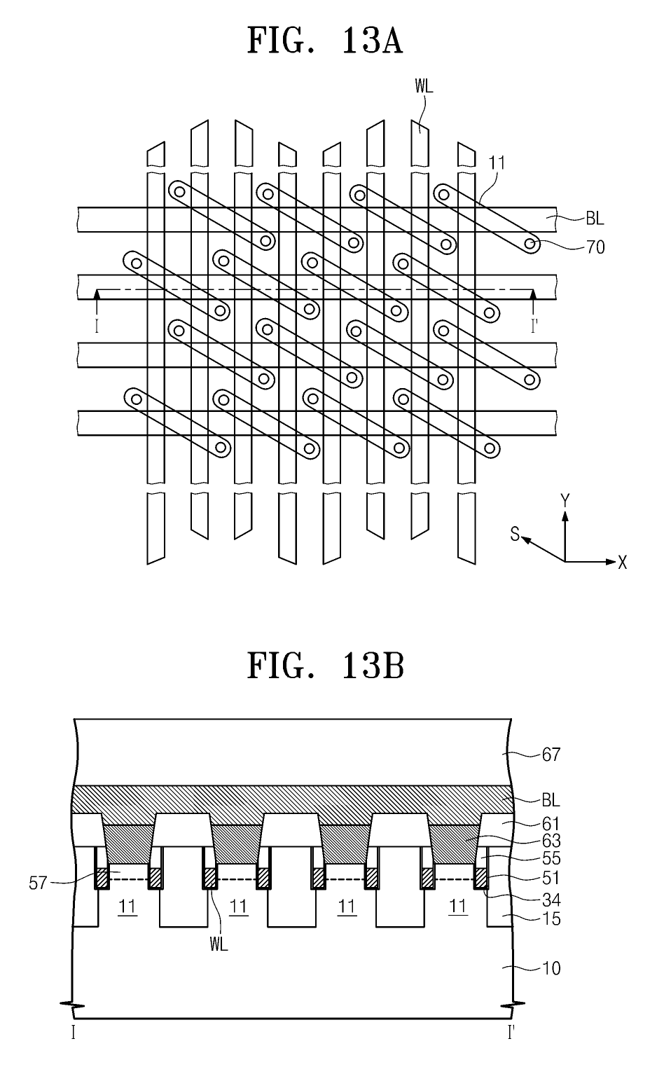

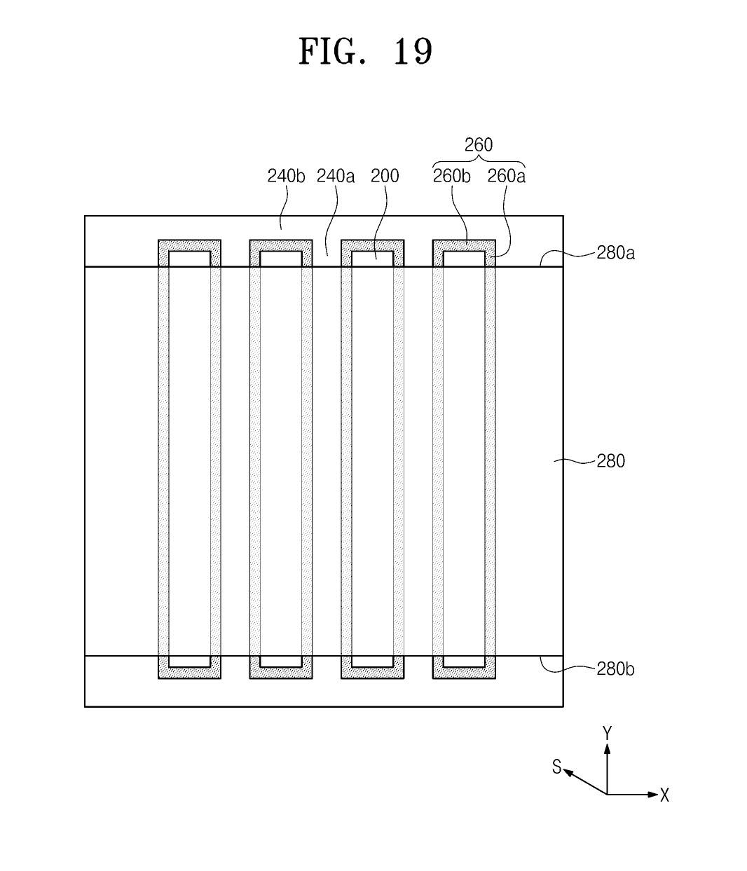

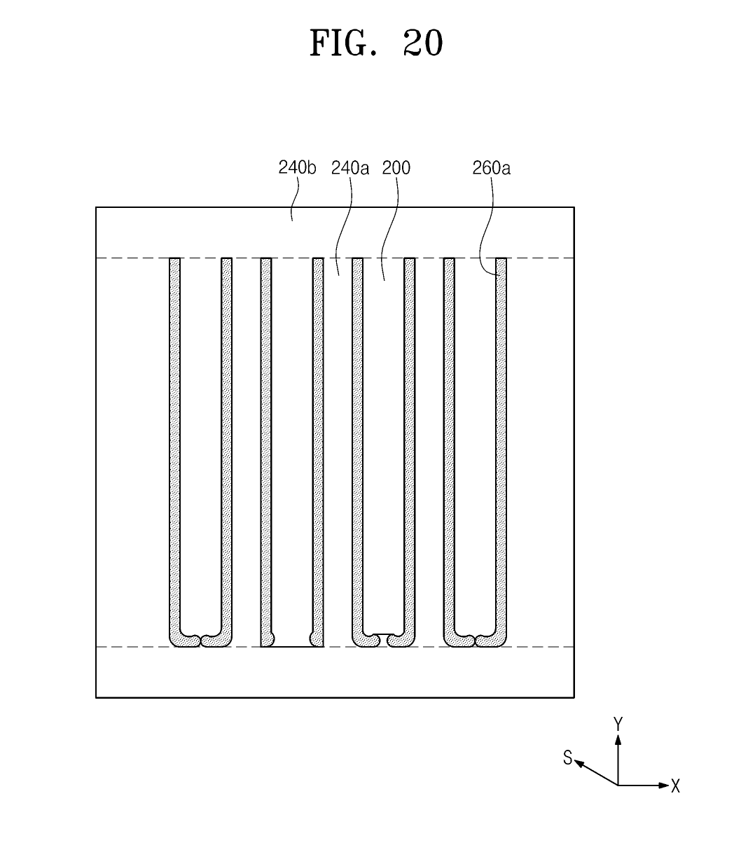

In certain embodiments, when the second sacrificial patterns 26b are etched using the trimming mask pattern 28 as the etch mask, the first mask patterns 20 exposed to the trimming mask pattern 28 may be etched simultaneously or faster than the second sacrificial patterns 26b. Consequently, the second sacrificial patterns 26b may not be exactly removed to trim and may be remained. Referring to FIGS. 19 and 20, a distance between the end portions of the first sacrificial patterns is small, for example, when using a trimming mask 280 that has sides with a straight line shape along the x direction, the end portions of the first sacrificial patterns 260a disposed adjacent to the both sides of the first mask patterns 200 may be connected each other. Thus, the openings adjacent to the first mask patterns may be connected to each other in the process of selectively etching the first sacrificial patterns. As a result, this may lead to an electric short between word lines (e.g., WL of FIGS. 13A and 13B), because the openings are used as a mold for forming the word lines in a subsequent process. By contrast, according to example embodiments of the inventive concept, it is possible to prevent such a problem from occurring, because the trimming mask pattern 28 with a periodic waveform shape is used as an etch mask in the process of etching the second sacrificial pattern 26b. For example, the use of the trimming mask pattern 28 makes it possible to increase a distance between the end portions of the first sacrificial patterns 26a adjacent to the first mask patterns 20 (e.g., in a y direction), when compared with the case in which the trimming mask pattern does not have a periodic waveform shape (e.g., compared to when the sides of the trimming mask pattern have a straight line shape along the x direction). For example, endpoints of a first sacrificial pattern 26a on one side of each first mask pattern 20 may be at a different location in the y direction than corresponding end points of a first sacrificial pattern 26a on the other side of each first mask pattern 20.

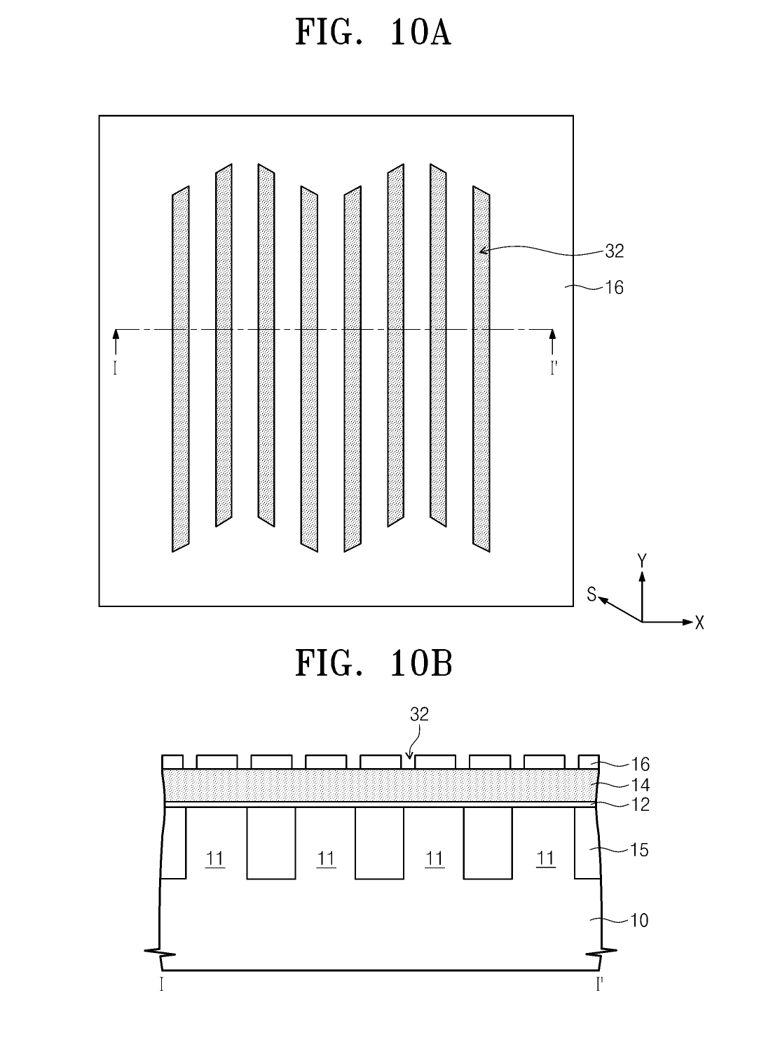

Referring to FIGS. 10A and 10B, the second thin-film 16 exposed by the openings 32 may be etched using the first to third mask patterns 20, 24a, and 24b as an etch mask. The first to third mask patterns 20, 24a, and 24b may also be etched during the etching of the second thin-film 16. In certain embodiments, although not illustrated, even after etching the second thin-film 16, a portion of the first to third mask patterns 20, 24a, and 24b may remain on the second thin-film 16.

Referring to FIGS. 11A and 11B, the carbon-containing layer 14 exposed by the openings 32 may be etched using the second thin-film 16 as an etch mask. The second thin-film 16 may also be etched or removed when the carbon-containing layer 14 is etched. In certain embodiments, although not illustrated, a portion of the second thin-film 16 may remain on the carbon-containing layer 14.

Referring to FIGS. 12A and 12B, the first thin-film 12 and the substrate 10 exposed by the openings 32 may be sequentially etched using the carbon-containing layer 14 as an etch mask. As a result, the substrate 10 may be patterned to form a plurality of gaps 34, also defined as fine gaps 34. When the substrate 10 and the first thin-film 12 are etched, the carbon-containing layer 14 may also be etched. For example, the carbon-containing layer 14 may be removed from the top surface of the first thin-film 12.

Referring to FIGS. 13A and 13B, an insulating layer 51 may be formed to conformally cover inner surfaces of the fine gaps 34, and then, word lines WL may be formed on the insulating layer 51. In one embodiment, the word lines WL may be formed to partially fill the fine gaps 34 (e.g., to fill a bottom portion of the gaps while not filling a top portion of the gaps).

The word lines WL may be, for example, conductive patterns that form conductive lines formed in the substrate. The word lines WL may be formed, for example, using a physical vapor deposition (PVD) process or an electroplating process. The word lines WL may be formed of or include, for example, at least one of metals including copper (Cu), tungsten (W), or aluminum (Al). The word lines WL may have shapes from a plan view that correspond to the shapes of the first sacrificial patterns 26a described for example in FIGS. 8A or 8C above. Further, as a result of the above process, the width of the gaps and resulting word lines may have dimensions smaller than the minimum width that can be achieved by a photolithography process.

The fine gaps 34 may be arranged to be spaced apart from each other in the second or x direction, and each of them may extend in the third or y direction. In example embodiments, two word lines WL may be disposed to cross each active region 11.

Buffer insulating patterns 55 may be formed in the fine gaps 34 provided with the word lines WL. In one embodiment, each of the buffer insulating patterns 55 may be formed to completely fill the remaining space of a corresponding one of the fine gaps 34. The buffer insulating patterns 55 may be formed of or include silicon oxide, silicon nitride, or silicon oxynitride, for example. The first thin-film 12 may be removed after the formation of the buffer insulating patterns 55.

Impurity regions 57 may be formed in the active region 11 between the word lines WL.

The impurity regions 57 may be formed to have bottom surfaces that are higher than those of the fine gaps 34. The insulating layer 51, the word lines WL, and the impurity regions 57 formed on the substrate 10 may constitute a transistor with a buried channel (i.e., BCAT).

Thereafter, a first interlayered insulating layer 61 may be formed on the substrate 10, and the first interlayered insulating layer 61 may be etched to form contact holes. The top surface of the substrate 10 may be recessed during the etching of the first interlayered insulating layer 61. Contact electrodes 63 may be formed to fill the contact holes, respectively. Next, bit lines BL may be formed on the first interlayered insulating layer 61. The contact electrodes 63 may be formed to partially fill the contact holes, and the bit lines BL may include portions filling the contact holes provided with the contact electrodes 63. The bit lines BL may be arranged on the substrate 10 to be spaced apart from each other in the third or y direction and extend in the second direction or x direction or across the word lines WL. In one embodiment, each of the bit lines BL may be formed to cross center regions of the active region 11. A second interlayered insulating layer 67 may be formed to cover the bit lines BL.

Contact plugs 70 may be formed on both end regions of the active region 11 that are not overlapped with the word lines WL and bit lines BL, in plan view. The contact plugs 70 may be respectively connected to capacitors (not shown), which will be formed thereon.

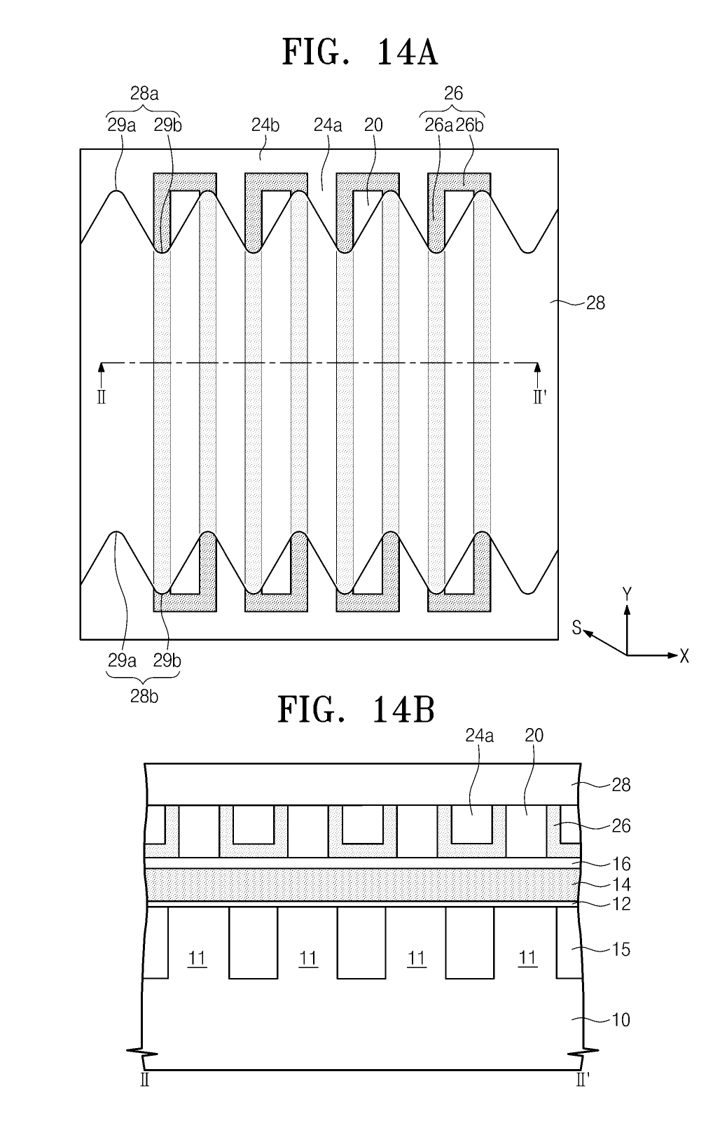

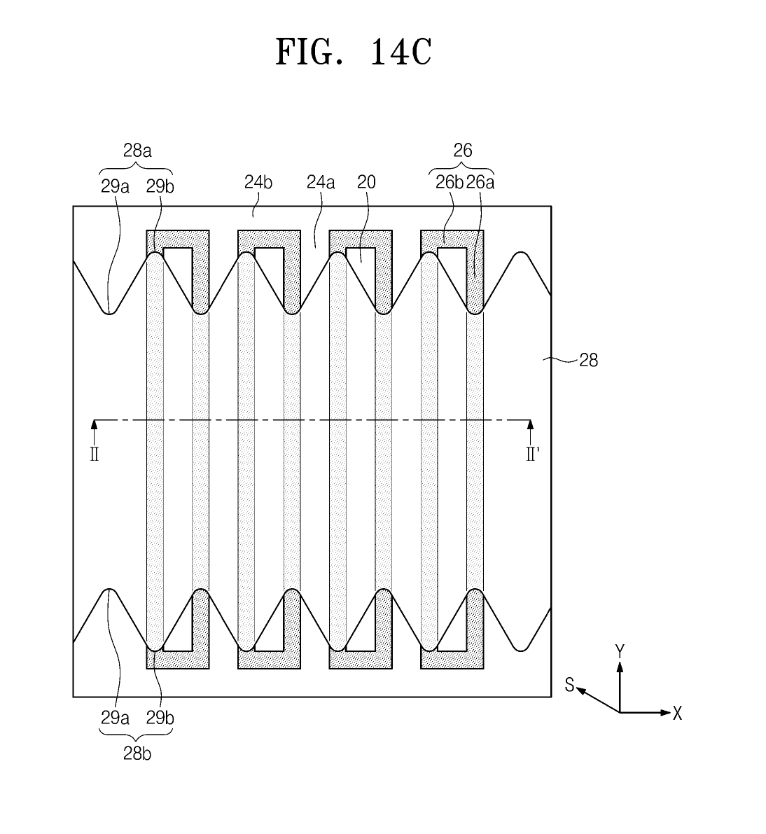

FIGS. 14A through 18A and FIGS. 14C and 15C are plan views illustrating a method of forming patterns for a semiconductor device, according to other example embodiments of the inventive concept. FIGS. 14B through 18B are sectional views, which are taken along line II-IP of FIGS. 14A through 18A and FIGS. 14C and 15C to illustrate a method of forming patterns for a semiconductor device according to other example embodiments of the inventive concept. For concise description, a previously described element may be identified by a similar or identical reference number without repeating an overlapping description thereof. In order to reduce complexity in the drawings and to provide better understanding of example embodiments of the inventive concepts, the active region 11 is omitted from FIGS. 14A through 17A and FIGS. 14C and 15C.

Referring to FIGS. 14A through 14C, the trimming mask pattern 28 may be formed on the first to the third mask patterns 20, 24a, and 24b to expose the second sacrificial pattern 26b described with reference to FIGS. 6A and 6B. Each of the first side 28a and the second side 28b of the trimming mask pattern 28 may include the first and second curved portions 29a and 29b. In each of the first side 28a and the second side 28b, the first and second curved portions 29a and 29b may be alternatingly formed along the x direction. When viewed in plan view, the first and second curved portions 29a and 29b may be curved toward two opposite directions. For example, the first curved portion 29a may be concavely curved, whereas the second curved portion 29b may be convexly curved. Similar to above, though curved portions are described, these portions of the periodic waveform shape may comprise bent portions that are not necessarily formed with a rounded curve, but may for example be formed of straight line portions that come together at an angle.

In example embodiments, as shown in FIG. 14A, the first side 28a may be formed in such a way that the first curved portions 29a thereof face (e.g., are opposite) the second curved portions 29b of the second side 28b.

In other example embodiments, as shown in FIG. 14C, the first side 28a may be formed in such a way that the first curved portions 29a thereof face the first curved portions 29a of the second side 28b.

The first and second curved portions 29a and 29b may be formed on the first sacrificial patterns 26a and may be connected to each other, for example, by linear portions that cross the first and second mask patterns 20 and 24a and are at an angle to the second or x direction.

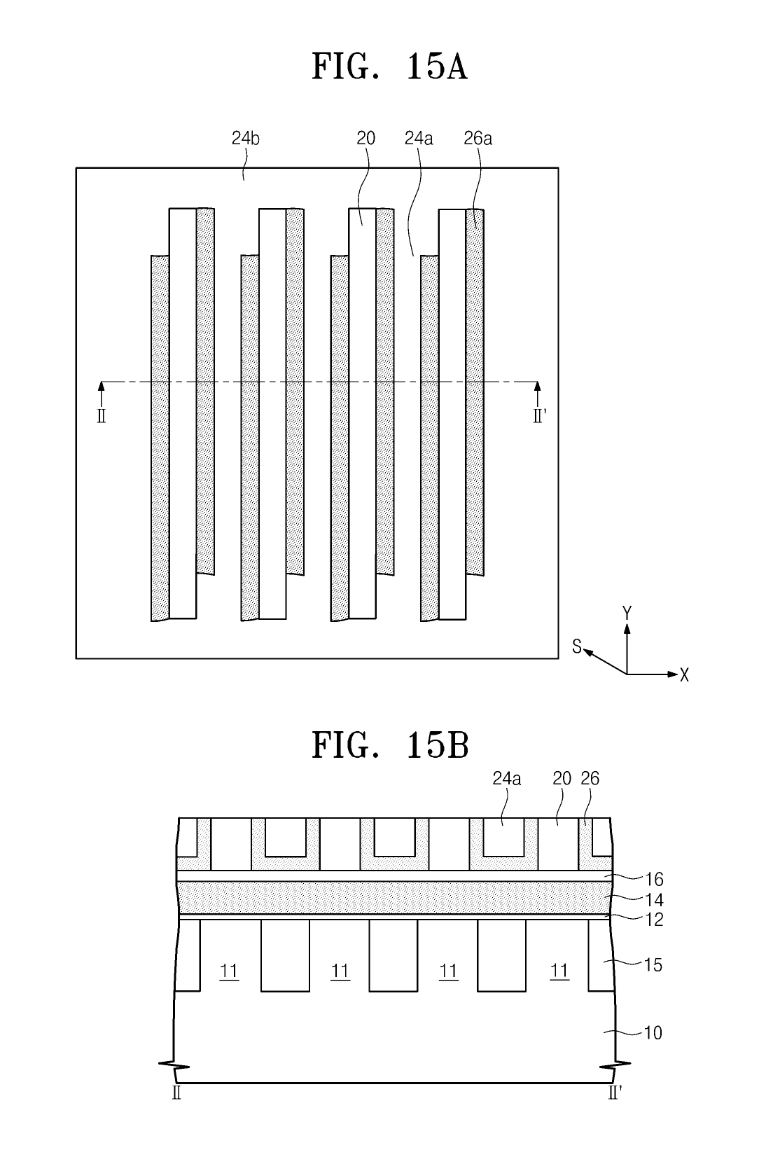

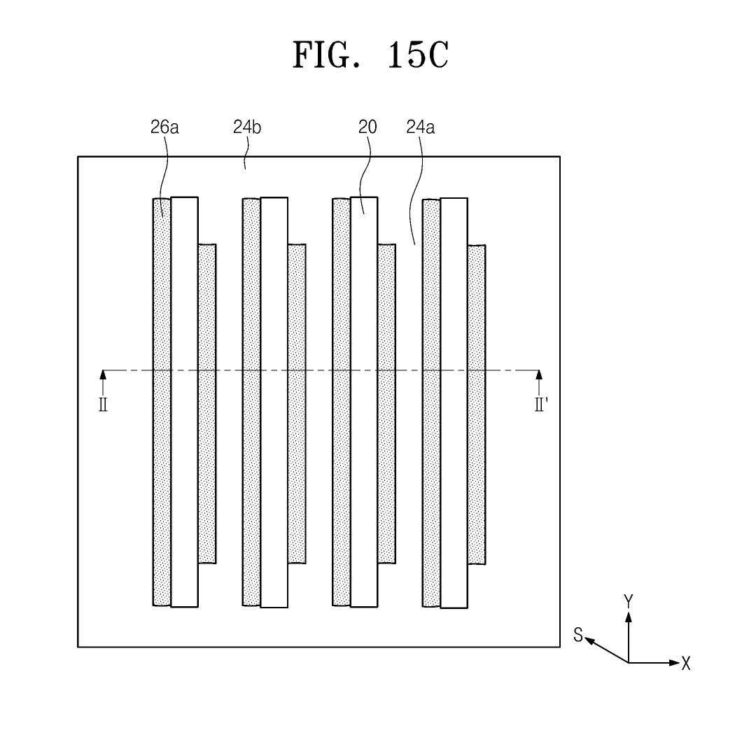

Referring to FIGS. 15A through 15C, the second sacrificial pattern 26b may be removed using the trimming mask pattern 28 as an etch mask. Since the trimming mask pattern 28 is used as the etch mask, the first sacrificial patterns 26a may remain between the first and second mask patterns 20 and 24a. A portion of the sacrificial patterns 26a, for example, at the ends of the sacrificial patterns 26a, may be removed. The remaining first sacrificial patterns 26a may be formed spaced apart from each other in the second or x direction.

In example embodiments, as shown in FIG. 15A, the first sacrificial patterns 26a may be formed to have substantially the same length. When viewed in plan view, a pair of adjacent first sacrificial patterns 26a disposed at opposite sides of the first mask patterns 20 may have end portions that are located at different positions in the y direction. Each corresponding end portion may also have a different type of bend from an adjacent corresponding end portion. For example, one end portion of a first sacrificial pattern 26a may be concavely shaped, while a corresponding end portion of an adjacent first sacrificial pattern 26a may be convexly shaped. A pair of the first sacrificial patterns 26a disposed at opposite sides of the second mask patterns 24a may have end portions that are located at different positions in the y direction. The first sacrificial patterns 26a disposed at first sides of the first mask patterns 20 may have end portions located at the same position in the y direction. The first sacrificial patterns 26a disposed at second, opposite sides of the first mask patterns 20 may have end portions located at the same position in the y direction. In the example shown in FIG. 15A, opposite end portions of each first sacrificial pattern 26a may have a different type of bend from each other. For example, one end portion may be concavely shaped, while the opposite end portion is convexly shaped.

In other example embodiments, as shown in FIG. 15C, the first sacrificial patterns 26a disposed at first sides of the first mask patterns 20 may be formed to have substantially the same length. The first sacrificial patterns 26a disposed at second, opposite sides of the first mask patterns 20 may be formed to have substantially the same length. The first sacrificial patterns 26a, which are respectively disposed at opposite sides of the first mask patterns 20, may be formed to have lengths different from each other. In this example as well, each corresponding end portion may also have a different type of bend from an adjacent corresponding end portion. For example, one end portion of a first sacrificial pattern 26a may be concavely shaped, while a corresponding end portion of an adjacent first sacrificial pattern 26a may be convexly shaped. Further, in the example shown in FIG. 15C, opposite end portions of each first sacrificial pattern 26a may have the same type of bend as each other. For example, both end portions may be concavely shaped, or both end portions may be is convexly shaped.

When viewed in plan view, the first sacrificial patterns 26a disposed at opposite sides of each of the first and second mask patterns 20 and 24a may have end portions that are located at different positions in the y direction. In addition, two of the first sacrificial patterns 26a, which are disposed at adjacent, opposite sides of another first sacrificial pattern 26a, may have end portions that are located at the same position in the y direction.

Thereafter, the trimming mask pattern 28 may be removed.

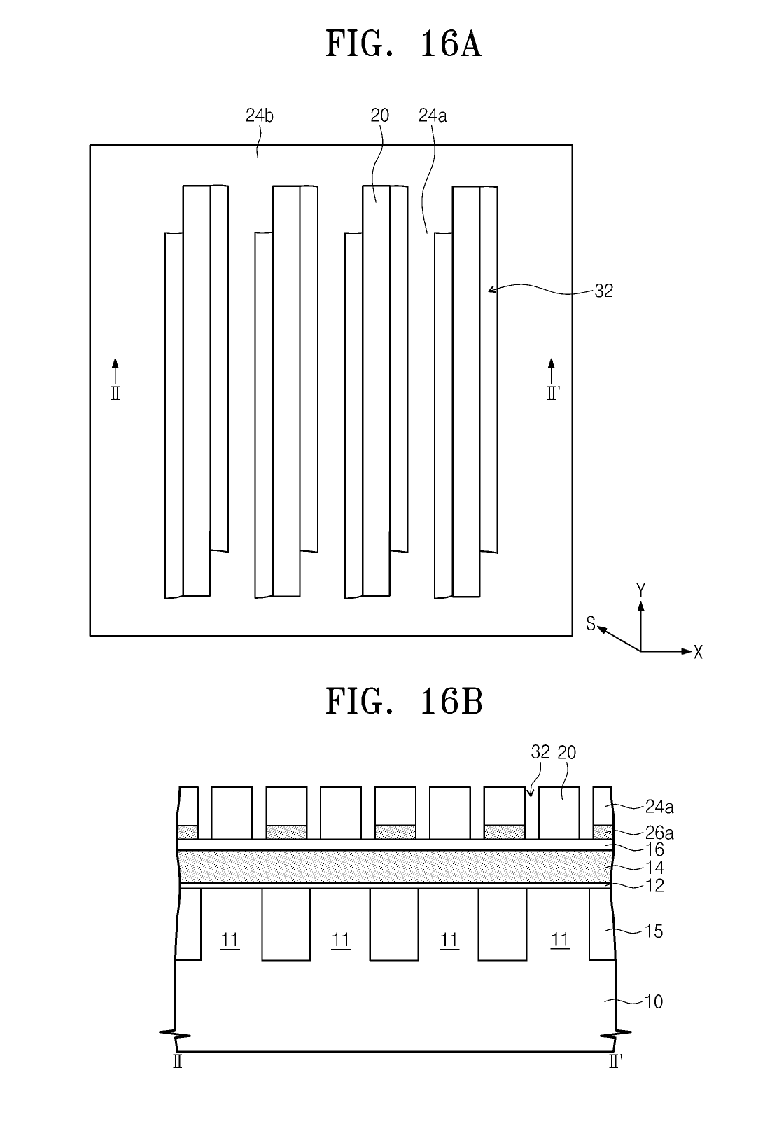

Referring to FIGS. 16A and 16B, the first sacrificial patterns 26a may be selectively etched using the first and second mask patterns 20 and 24a as an etch mask. Accordingly, the openings 32 may be formed between the first and second mask patterns 20 and 24a. Since the second mask patterns 24a is used as the etch mask, the first sacrificial patterns 26a may remain between the second thin-film 16 and the second mask patterns 24a.

Referring to FIGS. 17A and 17B, a patterning process may be performed to form a plurality of fine gaps 34 on the substrate 10. During the patterning process, the first and second mask patterns 20 and 24a defining the openings 32 may be used as an etch mask for forming the fine gaps 34.

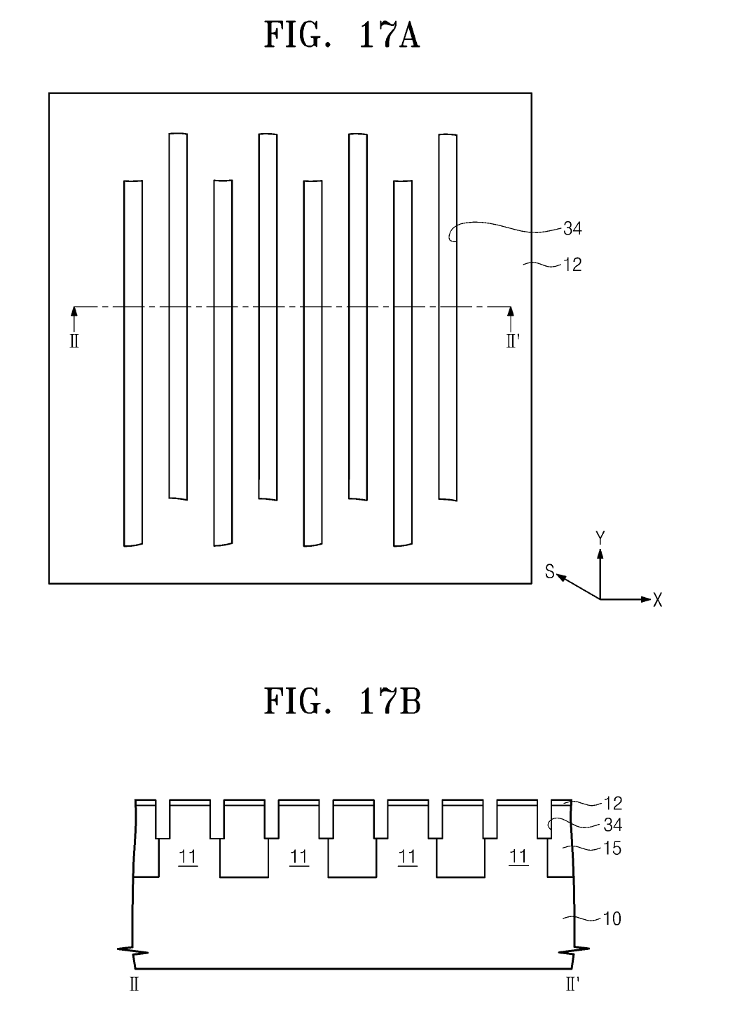

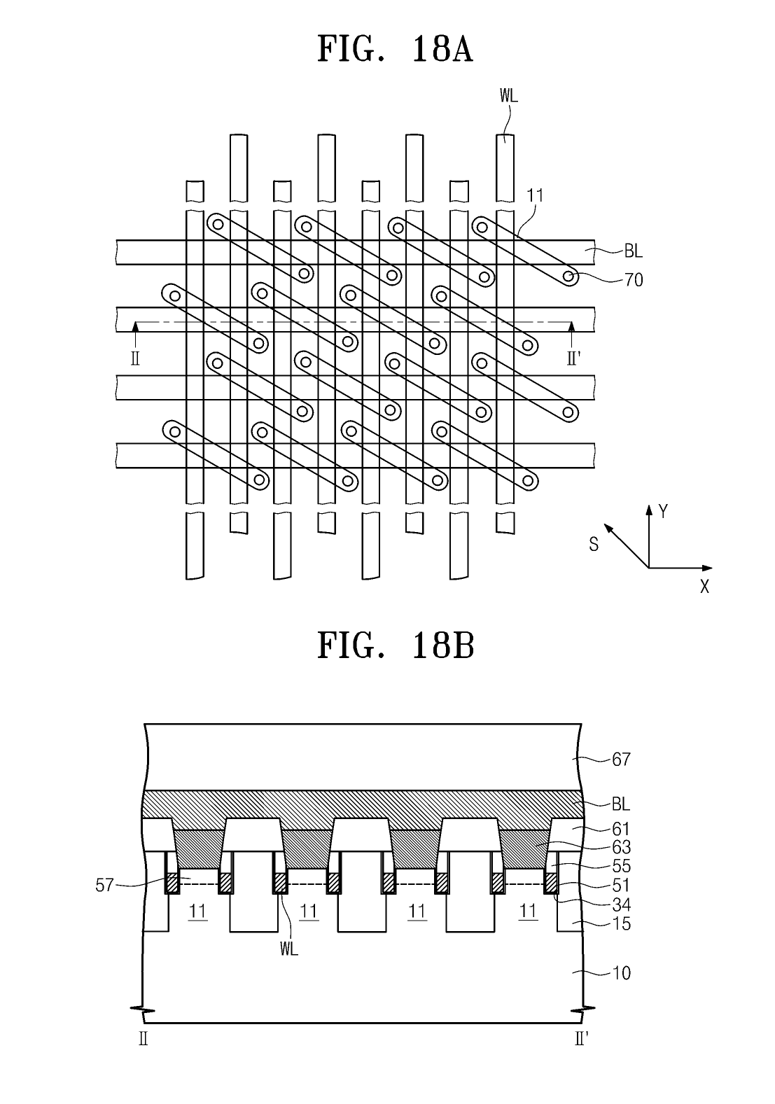

Referring to FIGS. 18A and 18B, the word lines WL and the buffer insulating patterns 55 may be formed to fill the fine gaps 34. The word lines WL may have shapes from a plan view that correspond to the shapes of the first sacrificial patterns 26a described for example in FIGS. 15A or 15C above.

The impurity regions 57 may be formed in the active region 11 between the word lines WL. The insulating layer 51, the word lines WL, and the impurity regions 57 formed on the substrate 10 may constitute a transistor with a buried channel (i.e., BCAT).

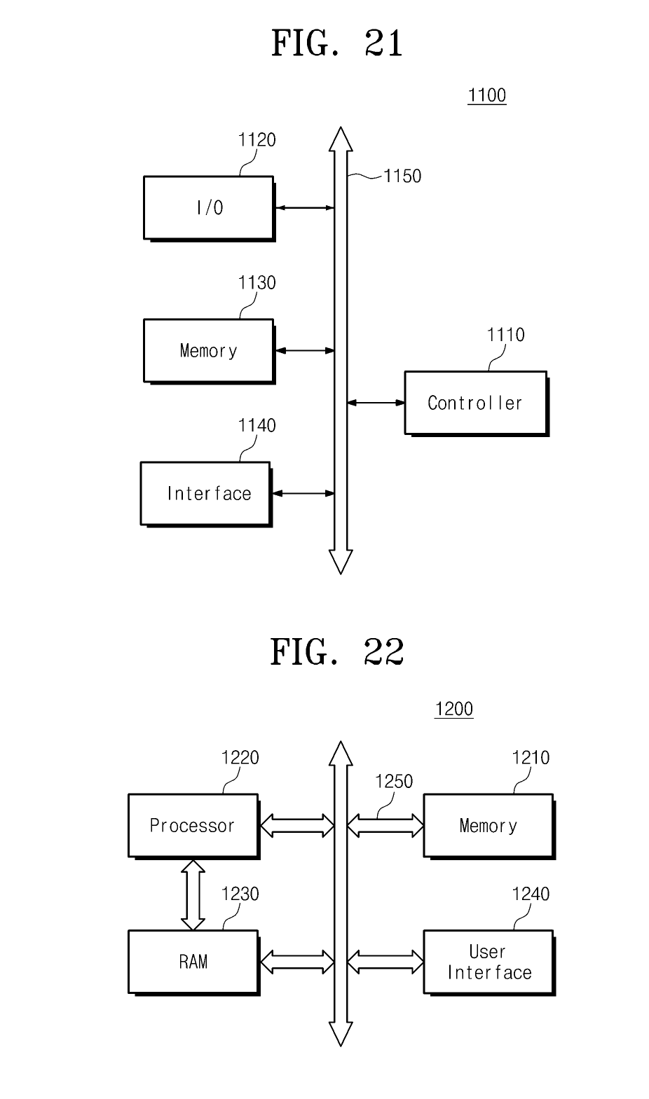

FIG. 21 is a schematic block diagram illustrating an example of electronic systems including a semiconductor device fabricated by the patterning method according to embodiments of the inventive concept.

As used herein, a semiconductor device may refer to any of the various devices such as shown in FIGS. 1-18, and may also refer, for example, to an array of transistors or a device such as a semiconductor chip (e.g., memory chip and/or logic chip formed on a die or wafer), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices.

An electronic device, as used herein, may refer to these semiconductor devices, but may additionally include products that include these devices, such as a memory module, memory card, hard drive including additional components, or a mobile phone, laptop, tablet, desktop, camera, or other consumer electronic device, etc.

Referring to FIG. 21, an electronic system 1100 may include a controller 1110, an input-output (I/O) unit 1120, a memory device 1130, an interface 1140, and a bus 1150. The controller 1110, the input-output unit 1120, the memory device 1130 and/or the interface 1140 may be connected or coupled to each other via the bus 1150 serving as a pathway for data communication. At least one of the controller 1110, the input-output unit 1120, the memory device 1130, and/or the interface 1140 may include a semiconductor device according to example embodiments of the inventive concept.

The controller 1110 may include, e.g., at least one of a microprocessor, a digital signal processor, a microcontroller, or another logic device. The other logic device may have a similar function to any one of the microprocessor, the digital signal processor, and the microcontroller.

The input-output unit 1120 may include a keypad, keyboard, a display device, and so forth. The memory device 1130 may be configured to store data and/or command. The interface unit 1140 may transmit electrical data to a communication network or may receive electrical data from a communication network. The interface unit 1140 may operate by wireless or cable, for example. For example, the interface unit 1140 may include an antenna for wireless communication or a transceiver for cable communication. Although not shown in the drawings, the electronic system 1100 may further include a fast DRAM device and/or a fast SRAM device which acts as a cache memory for improving an operation of the controller 1110.

The electronic system 1100 may be applied to an electronic device such as, for example, a personal digital assistant (PDA), a portable computer, a web tablet, a wireless phone, a mobile phone, a digital music player, a memory card, or other electronic products. The other electronic products may receive or transmit information data by wireless.

FIG. 22 is a schematic block diagram illustrating another example of electronic systems including a semiconductor memory device fabricated by a patterning method according to embodiments of the inventive concept.

Referring to FIG. 22, an electronic system 1200 may include at least one of the semiconductor memory devices according to the embodiments mentioned above. The electronic system 1200 may include a mobile device or a computer. As an illustration, the electronic system 1200 may include a memory system 1210, a processor 1220, a random access memory (RAM) 1230, and a user interface 1240 that that are electrically connected to a bus 1250.

The processor 1220 may be configured to execute programs and control the electronic system 1200. The RAM 1230 may be used as an operating memory of the processor 1220. For example, all or each of the processor 1220 and the RAM 1230 may include the semiconductor device according to example embodiments of the inventive concept. Alternatively, the processor 1220 and the RAM 1230 may be provided as components of a semiconductor package. The user interface 1240 may be used to input/output data to/from the electronic system 1200. The memory system 1210 may be configured to store code for operating the processor 1220, data processed by the processor 1220 or data inputted from the outside. The memory system 1210 may include a controller and a memory device.

The electronic system 1200 may be realized as a mobile system, a personal computer, an industrial computer, or a logic system performing various functions. For example, the mobile system may be one of a personal digital assistant (PDA), a portable computer, a web tablet, a wireless phone, a mobile phone, a laptop computer, a digital music system, and an information transmit/receive system. When the electronic system 1200 performs wireless communication, the electronic system 1200 may be used in a communication interface protocol of a communication system such as CDMA, GSM, NADC, E-TDMA, WCDMA, CDMA2000, Wi-Fi, Muni Wi-Fi, Bluetooth, DECT, Wireless USB, Flash-OFDM, IEEE 802.20, GPRS, iBurst, WiBro, WiMAX, WiMAX-Advanced, UMTS-TDD, HSPA, EVDO, LTE-Advanced, MMDS, and so forth.

According to example embodiments of the inventive concept, provided is a patterning method capable of preventing an electric short from occurring between conductive patterns. Accordingly, the use of the pattering method allows for improvement in reliability of a semiconductor device.

While example embodiments of the inventive concepts have been particularly shown and described, it will be understood by one of ordinary skill in the art that variations in form and detail may be made therein without departing from the spirit and scope of the attached claims.

What is claimed is:

1. A method of manufacturing a semiconductor device, the method comprising:
forming a plurality of first mask patterns on a substrate, the plurality of first mask patterns being arranged along a first direction and extending in a second direction;
forming a plurality of second mask patterns on the substrate arranged along the first direction, each second mask pattern disposed between two first mask patterns and extending in the second direction;
forming a sacrificial layer to enclose the first mask patterns, the sacrificial layer comprising first portions disposed on sidewalls of the first mask patterns to face each other in the first direction and second portions disposed at ends of the first mask patterns to connect the first portions to each other; and
removing the second portions of the sacrificial layer using a trimming mask pattern as an etch mask to form sacrificial patterns spaced apart from each other in the first direction, each sacrificial pattern having two opposite end portions in the second direction,
wherein each sacrificial pattern has at least one different end portion location in the second direction from a corresponding end portion location of at least one adjacent sacrificial pattern.

2. The method of claim 1, wherein:
each sacrificial pattern has two end portion locations in the second direction different from two corresponding end portion locations of at least one adjacent sacrificial pattern.

3. The method of claim 2, further comprising:
removing the plurality of sacrificial patterns, and forming a plurality of conductive lines in a plurality of gaps formed in the substrate, the gaps corresponding to and formed to have the same shapes as the plurality of sacrificial patterns from a plan view.

4. The method of claim 3, wherein the width of the conductive lines is smaller than the minimum width that can be achieved by a photolithography process.

5. The method of claim 1, wherein at least one sacrificial pattern has an end portion that is either concavely shaped or that has a straight line shape angled with respect to the first direction.

6. The method of claim 1, wherein:
when viewed in a plan view, the trimming mask pattern comprises a first side and a second side, which are opposite each other in the second direction, the first side having a periodic waveform shape.

7. The method of claim 6, wherein:
the second side of the trimming mask pattern also has a periodic waveform shape.

8. The method of claim 7, wherein:
the shape of the first side of the trimming mask is either in phase with or is 180 degrees out of phase with the shape of the second side of the trimming mask.

9. The method of claim 1, wherein one sacrificial pattern has a shape that is a mirror image of a first adjacent sacrificial pattern on one side of the one sacrificial pattern, and that is not a mirror image of a second adjacent sacrificial pattern on the other side of the one sacrificial pattern.

10. The method of claim 1, wherein each sacrificial pattern is formed to have substantially the same length.

11. The method of claim 1, wherein the forming of the sacrificial layer comprises:
conformally forming a preliminary sacrificial layer on the substrate formed with the first mask patterns; and
etching the preliminary sacrificial layer to expose top surfaces of the first mask patterns.

12. The method of claim 1, further comprising:
etching the sacrificial patterns using the first and second mask patterns as an etch mask to form openings exposing the substrate;
etching the substrate exposed by the openings to form gaps in the substrate; and
forming conductive patterns to fill the gaps, respectively.

13. The method of claim 12, wherein the conductive patterns are formed to partially fill the gaps, thereby serving as buried gate patterns.

14. The method of claim 13, further comprising:
forming an insulating layer on inner surfaces of the gaps, before the forming of the conductive patterns;
forming buffer insulating patterns to fill the gaps provided with the conductive patterns; and
forming impurity regions in portions of the substrate located between the gaps.

15. A method of manufacturing a semiconductor device, the method comprising:
forming a substrate;
forming a plurality of first patterns on the substrate, the plurality of first patterns spaced apart from each other in a first direction and extending in a second direction, each first pattern having two opposite end portions in the second direction, and each first pattern having at least one different end portion location in the second direction from a corresponding end portion location of at least one adjacent first pattern; and
using the plurality first patterns to form a plurality of respective conductive lines in a plurality of gaps formed in the substrate, the gaps corresponding to and formed to have the same shapes as the plurality of first patterns when viewed from a plan view.

16. The method of claim 15, wherein:
each first pattern has two end portion locations in the second direction different from two corresponding end portion locations of at least one adjacent first pattern.

17. The method of claim 16, wherein:
the width of the conductive lines is smaller than the minimum width that can be achieved by a photolithography process.

18. The method of claim 16, further comprising:
forming an insulating layer on inner surfaces of the gaps, before the forming of the conductive lines;
forming buffer insulating patterns to fill the gaps provided with the conductive lines; and
forming impurity regions in portions of the substrate located between the gaps.

19. The method of claim 15, wherein the first patterns are formed using a trimming mask that includes a first side that has a periodic waveform shape when viewed in a plan view.

20. A method of manufacturing a semiconductor device, the method comprising:
forming a substrate; and
forming a plurality of sacrificial patterns on the substrate, the plurality of sacrificial patterns spaced apart from each other in a first direction and extending in a second direction, each sacrificial pattern having two opposite end portions in the second direction,
wherein each sacrificial pattern has two end portions having end portion locations in the second direction different from corresponding end portion locations of two end portions of at least one adjacent sacrificial pattern, and
wherein the sacrificial patterns are formed using a trimming mask that includes a first side that has a zig-zag shape when viewed in a plan view.
